(19) United States
(12) Patent Application Publication
(10) Pub. No.: US 2012/0094025 A1
(43) Pub. Date: Apr. 19, 2012

(54) Substrate Depositing System and Method

(75) Inventors: Sun-Ho Kim, Yongin-City (KR); Cheol-Lae Roh, Yongin-City (KR); Suk-Won Jung, Yongin-City (KR); Hyun Choi, Yongin-City (KR); Min-Gyu Seo, Yongin-City (KR)

(73) Assignee: SAMSUNG MOBILE DISPLAY CO., LTD., Yongin-City (KR)

(21) Appl. No.: 13/186,944

(22) Filed: Jul. 20, 2011

(30) Foreign Application Priority Data
Oct. 18, 2010 (KR) 10-2010-0101411

(51) Int. Cl. B05D 5/00; B05C 11/00; B05C 13/00

(52) U.S. Cl. 427/282; 118/500; 118/75

(57) ABSTRACT

A substrate depositing system comprises a substrate loading chamber for receiving a substrate, a substrate unloading chamber for withdrawing the substrate, at least one process chamber disposed between the substrate loading chamber and the substrate unloading chamber for processing the substrate, and a mask keeping chamber connected to one side of the process chamber(s). A substrate depositing method comprises inputting a substrate into a process chamber, transferring a mask to the process chamber from a mask keeping chamber connected to the process chamber, aligning the substrate and the mask, depositing a depositing material on the substrate while moving a deposition source in the process chamber, and withdrawing the substrate from the process chamber.

### CLAIM OF PRIORITY

This application makes reference to, incorporates the same herein, and claims all benefits accruing under 35 U.S.C. §119 from an application earlier filed in the Korean Intellectual Property Office on the 18 of Oct. 2010 and there duly assigned Serial No. 10-2010-0101411.

### BACKGROUND OF THE INVENTION

1. Field of the Invention

The present invention relates generally to a substrate depositing system and method. More particularly, the invention relates generally to an inline substrate depositing system with process chambers arranged in series, and a depositing method using the same.

2. Description of the Related Art

An organic light emitting diode (OLED) display is a flat display device which has a self emissive characteristic, and which does not require a separate light source so that it can be made lightweight and thin. Particularly, the OLED display exhibits quality characteristics such as low power consumption, high luminance, and high response speed, and as such, the OLED display receives much attention as a next-generation display device.

In general, the OLED display includes an organic light emitting element which includes an anode, an organic emission layer, and a cathode. Holes and electrons are injected from the anode and the cathode, respectively, to form excitons, and the excitons make a transition to a ground state, thereby causing the organic light emitting diode to emit light.

The anode and the cathode can be formed with a metal thin film or a transparent conductive thin film, the organic emission layer can be formed with at least one organic thin film, and a vacuum depositing method can be used to form the organic thin film or the metal thin film on a substrate of the OLED display. As a general method to form an organic thin film and a metallic thin film, the vacuum deposition method is used to form an organic thin film in a vapor deposition apparatus, which includes a material evaporation source having a crucible, by inserting a vapor deposition material in the crucible and depositing the vapor deposition material by heating the crucible to a predetermined temperature.

A cluster depositing system or an inline depositing system can be used to form the organic thin film and the metal thin film according to the vacuum depositing method. The inline depositing system includes a substrate loading chamber, a substrate unloading chamber, and a plurality of process chambers disposed in series therebetween, and it can reduce process time compared to the process time of the cluster-type depositing system.

In general, in each process chamber, a depositing material such as an organic material or a metal is deposited on the substrate by using a deposition source, and a mask for realizing a high-resolution organic light emitting element is used to form an organic thin film and a metal thin film on the substrate.

Hence, the substrate and the mask must be aligned before the depositing material is deposited on the substrate, and for this purpose, a method for providing the aligned substrate and the mask in the substrate loading chamber has been proposed. However, when the aligned substrate and the mask are provided together, if a problem occurs in the mask while the depositing process is performed and the mask must be replaced, it is necessary to stop the entire process, to transfer the substrate and the mask to the substrate unloading chamber, to realign them, and to provide them again. Accordingly, the depositing process becomes complicated and the process time is increased.

Also, patterns of a plurality of deposited organic thin films and metal thin films are different so that the entire process time is increased for the same reason that process time is increased when the mask is replaced in each process chamber.

The above information disclosed in this Background section is only for enhancement of an understanding of the background of the described technology, and therefore it may contain information which does not form the prior art which is already known in this country to a person of ordinary skill in the art.

### SUMMARY OF THE INVENTION

The present invention has been developed in an effort to provide a substrate depositing system for realizing a high-resolution organic light emitting element without forming a large system.

The present invention has also been developed in an effort to provide a depositing method for increasing productivity by reducing the entire process time.

An exemplary embodiment of the invention comprises a substrate depositing system which includes: a substrate loading chamber for receiving a substrate; a substrate unloading chamber for withdrawing the substrate; at least one process chamber disposed between the substrate loading chamber and the substrate unloading chamber; and a mask keeping chamber connected to one side of the process chamber(s).

The substrate depositing system further includes a substrate transferring device for penetrating the process chamber(s).

The substrate depositing system further includes a substrate fixing device for receiving the substrate and then being transferred along the substrate transferring device.

The substrate depositing system further includes a mask transferring device penetrating at least one mutually connected process chamber and the mask keeping chamber.

The substrate depositing system further includes a mask fixing device for receiving a mask and then being transferable along the mask transferring device.

The substrate depositing system includes a deposition source for depositing a depositing material onto the substrate in the process chamber(s).

The substrate depositing system further includes a deposition source guide member disposed at the bottom of the deposition source for transferring the deposition source in a given direction.

The substrate depositing system further includes a mask cleansing chamber connected to the mask keeping chamber.

The mask cleansing chamber is a plasma cleansing chamber.

Another embodiment of the invention provides a substrate depositing method comprising the steps of: inputting a substrate into a process chamber; transferring a mask to the process chamber from a mask keeping chamber connected to the process chamber; aligning the substrate and the mask; depositing a depositing material on the substrate while moving a deposition source in the process chamber; and withdrawing the substrate from the process chamber.

The process chamber(s) is (are) arranged in series with a substrate loading chamber and a substrate unloading chamber, and respective stages in the process chamber(s) is (are) repeated.

The substrate is inputted and taken out by using a substrate transferring device penetrating the process chamber(s), and the mask is transferred by using a mask transfer device for connecting the process chamber(s) and the mask keeping chamber.

The substrate and the mask are received in a substrate fixing device and a mask fixing device, respectively, and the substrate fixing device and the mask fixing device are movable on the substrate transferring device and the mask transferring device, respectively.

The deposition source moves in a direction crossing the direction in which the substrate is inputted and withdrawn.

The substrate depositing method further includes the step, after the depositing of a substrate, of transferring the mask to a mask cleansing chamber connected to the mask keeping chamber for cleansing the mask.

The cleansing of the mask includes cleansing the mask by using plasma.

According to the exemplary embodiments, the mask can be replaced without stopping the process, and the process time can be reduced by including a mask keeping chamber.

Furthermore, the system cost can be reduced since a large system is not needed.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIG. 1 is a schematic diagram of a substrate depositing system according to a first exemplary embodiment of the invention.

FIG. 2 depicts a process chamber of a substrate depositing system according to a first exemplary embodiment of the invention.

FIG. 3A thru FIG. 3E sequentially show a process for depositing a depositing material on a substrate in a process chamber of a substrate depositing system according to a first exemplary embodiment of the invention.

FIG. 4 is a schematic diagram of a substrate depositing system according to a second exemplary embodiment of the invention.

### DETAILED DESCRIPTION OF THE INVENTION

The present invention will be described more fully hereinafter with reference to the accompanying drawings, in which exemplary embodiments of the invention are shown. Like reference numerals designate like elements throughout the specification. The size and thickness of each component shown in the drawings are arbitrarily shown for understanding and ease of description, but the present invention is not limited thereto.

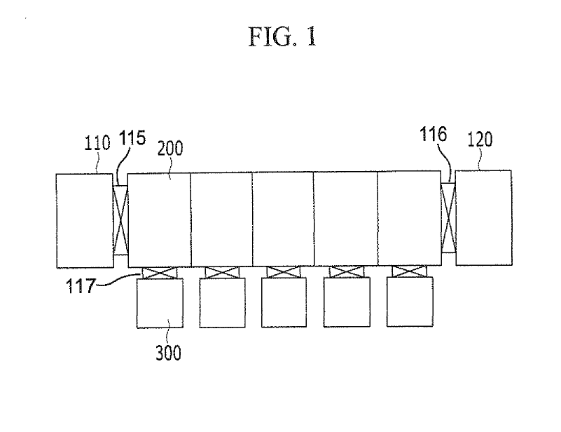

FIG. 1 is a schematic diagram of a substrate depositing system according to a first exemplary embodiment of the invention.

Referring to FIG. 1, the substrate depositing system includes a substrate loading chamber 110, a substrate unloading chamber 120, and at least one process chamber 200 disposed between the substrate loading chamber 110 and the substrate unloading chamber 120, and arranged in series (i.e., in an inline manner). It also includes a mask keeping chamber 300 disposed on one side of each process chamber 200.

The substrate, on which the depositing material such as an organic material or a metal is deposited, is provided to the substrate depositing system through the substrate loading chamber 110. The depositing material is deposited so as to form an organic thin film on the substrate in each process chamber 200, and the organic thin film is outputted through the substrate unloading chamber 120.

The number of process chambers 200 is determined so as to correspond to a number of thin films formed on the substrate. The organic thin film formed on the substrate includes an emission layer (EML), and further includes at least one of a hole injection layer (HIL), a hole transport layer (HTL), an electron transporting layer (ETL), and an electron injection layer. Also, a metal thin film or a transparent conductive thin film functioning as the cathode and the anode can be further formed on the substrate. The thin films are formed in different process chambers 200 so that the number of process chambers 200 is determined according to the number of deposited organic thin films and metal thin films.

As described above, the substrate depositing system includes at least one mask keeping chamber 300. Each mask keeping chamber 300 is connected to a side of a respective process chamber 200, and in detail, it can be connected to the process chamber 200 in a direction which crosses the direction in which the substrate loading chamber 110, the substrate unloading chamber 120, and the process chamber 200 are arranged in series. The mask keeping chamber 300 stores a mask used to deposit the depositing material, such as the organic material or the metal, in the process chamber 200, and the mask is transferred to the process chamber 200 and aligned with the substrate during the depositing process.

In order to maintain a vacuum state in the process chamber 200 while the depositing material is deposited in the process chamber 200, an exhaust pipe (not shown) to which a vacuum pump (not shown) is installed may be connected to the process chamber 200.

Also, a gate valve 115 can be formed between the substrate loading chamber 110 and the process chambers 200, and a gate valve 116 can be formed between the process chambers 200 and the substrate unloading chamber 120. A gate valve 117 can also be formed between each process chamber 200 and a mask keeping chamber 300. Finally, a gate valve (not shown) can be formed between adjacent process chambers 200. The gate valve is opened while the substrate or the mask moves, and is closed while the organic material depositing process is performed so that the organic material depositing process may be performed in a vacuum state.

The substrate depositing system may further include a substrate cleansing chamber (not shown). The substrate cleansing chamber cleanses the substrate by using plasma or ultraviolet (UV) rays before it is arranged between the substrate loading chamber 110 and the process chamber 200, and deposits the depositing material on the substrate.

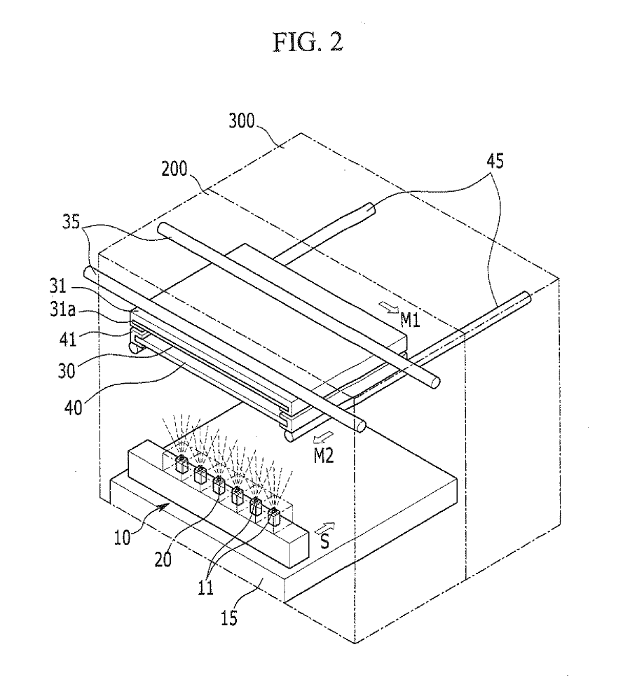

FIG. 2 depicts a process chamber of a substrate depositing system according to a first exemplary embodiment of the invention. The configuration of the substrate depositing system will now be described in further detail.

Referring to FIG. 2, a substrate transferring device 35 is formed so as to pass through the process chamber 200, and a substrate fixing device 31 is formed so as to move along the substrate transferring device 35. Accordingly, a substrate 30 provided through the substrate loading chamber 110 is transferred to the process chamber 200 by following the substrate transferring device 35 while being provided in the substrate fixing device 31. In this instance, the direction M1 for transferring the substrate 30 corresponds to the direction in which the substrate loading chamber 110, the substrate unloading chamber 120, and the process chamber 200 are arranged in series.

In the present exemplary embodiment, the substrate transferring device 35 is exemplified as being formed in a rail shape, but the present invention is not restricted thereto, and a plurality of cylindrical rods functioning as a roller can be arranged in the substrate transfer direction M1. Also, the substrate fixing device 31 is formed so as to be a tray for receiving the substrate 30, and the substrate fixing device 31 is configured to receive the substrate 30 and to be moved along the substrate transferring device 35 which is variable in many ways as would be known to a person of ordinary skill in the art.

As described above, the mask keeping chamber 300 is connected to the process chamber 200. The mask keeping chamber 300 stores a mask 40 needed according to types of the organic thin film and the metal thin film formed by each process chamber 200, and the mask 40 is transferred to the process chamber 200 during the organic material depositing process.

For this purpose, a mask transferring device 45 is formed so as to penetrate the process chamber 200 and the mask keeping chamber 300, and a mask fixing device 41 is formed so as to be moved along the mask transferring device 45. Accordingly, the mask 40 kept in the mask keeping chamber 300 is transferred to the process chamber 200 by the mask transferring device 45 while being received in the mask fixing device 41. In this instance, the direction M2 in which the mask 40 is transferred crosses the direction M1 in which the substrate 30 is transferred.

The mask transferring device 45 can be formed as a rail in a manner similar to the substrate transferring device 35, and the mask fixing device 41 can be formed in various forms so as to receive the mask 40 and to be moved along the mask transferring device 45. However, in contrast to the substrate fixing device 31, in the mask fixing device 41, a side facing the substrate 30 and an opposite side are formed so as to be opened so that the organic material sprayed in the lower direction, with reference to FIG. 2, may be transmitted through the mask 40 and deposited to the substrate 30.

As described above, a gate valve 115 (FIG. 1) may be formed between the process chamber 200 and the adjacent substrate loading chamber 110, a gate valve 116 may be formed between process chamber 200 and the substrate unloading chamber 120, and a gate valve (not shown) may be formed between adjacent process chambers 200, in the transfer direction M1 (FIG. 2) of the substrate 30. While the depositing material is deposited on the substrate, the gate valve is closed so as to maintain a vacuum state in the process chamber 200. Also, a gate valve 117 (FIG. 1) may be formed between the process chamber 200 and the mask keeping chamber 300 for the same purpose.

A deposition source 10 (FIG. 2) for spraying the depositing material, such as an organic material or a metal, onto the substrate 30 is disposed in the process chamber 200. The deposition source 10 includes a crucible for storing the depositing material, such as an organic material or a metal, a heater for heating the crucible so as to vaporize or sublimate the depositing material, and at least one nozzle 11 connected to the crucible of deposition source 10. When the depositing materials are an organic material, a metal, and a transparent conductive material, respectively, the material of the crucible and the temperature produced by the heater may become different because the vaporization or sublimation temperatures are different, but the methods for depositing the respective materials are the same, so that the shape of the deposition source 10 and its disposal in each process chambers 200 are the same in the present exemplary embodiment.

The deposition source 10 is disposed so that at least one nozzle 11 may face the substrate 30, and the depositing material vaporized or sublimated by the crucible is sprayed onto the substrate 30 through the nozzle 11. The present exemplary embodiment exemplifies a linear deposition source in which a plurality of nozzles 11 are arranged in series in one direction on the deposition source 10, but the deposition source 10 may be variable as known to a person of ordinary skill in the art.

A cover plate 20 may be formed near each nozzle 11. As shown in FIG. 2, the cover plate 20 can be formed so as to surround the nozzle 11 or a plurality of adjacent nozzles 11. The cover plate 20 controls a deposition angle of the depositing material outputted by the nozzle 11 so that the organic material may be uniformly deposited on the substrate 30.

The deposition source 10 is supported by a deposition source guide member 15 installed at the bottom, and can be transferred in the scan direction S of the deposition source. That is, while the substrate 30 is stopped in the process chamber 200, the deposition source 10 is moved in the scan direction S so as to spray the depositing material and uniformly deposit the depositing material on the substrate 30.

Accordingly, since the mask keeping chamber 300 is disposed to one side of the process chamber 200, the mask 40 can be replaced in the mask keeping chamber 300 without stopping the entire process when a problem is generated at the mask 40 during the deposition process.

Furthermore, since the substrate 30 and the mask 40 are individually provided in the process chamber 200 and are aligned therein, the depositing material can be deposited without additionally disposing a chamber for aligning the mask and the substrate, so that a high-resolution organic light emitting element can be formed without forming the whole substrate depositing system in a large manner.

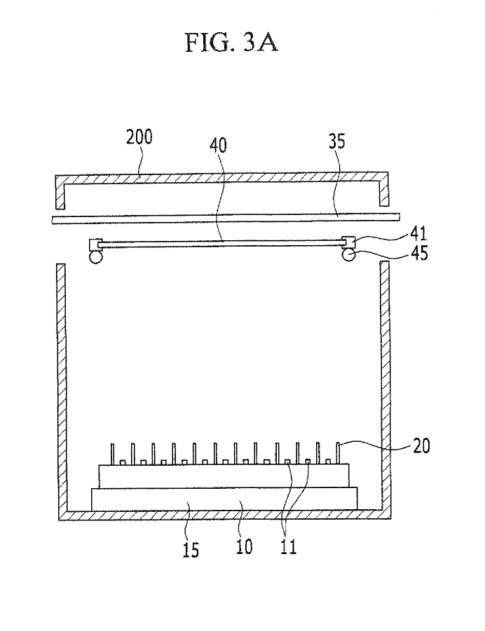

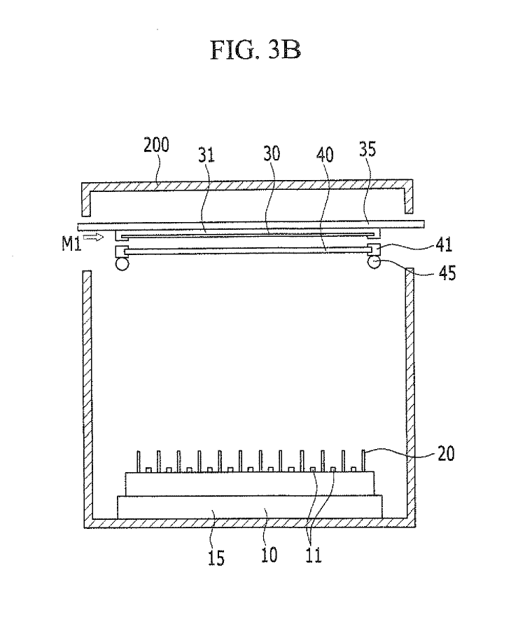

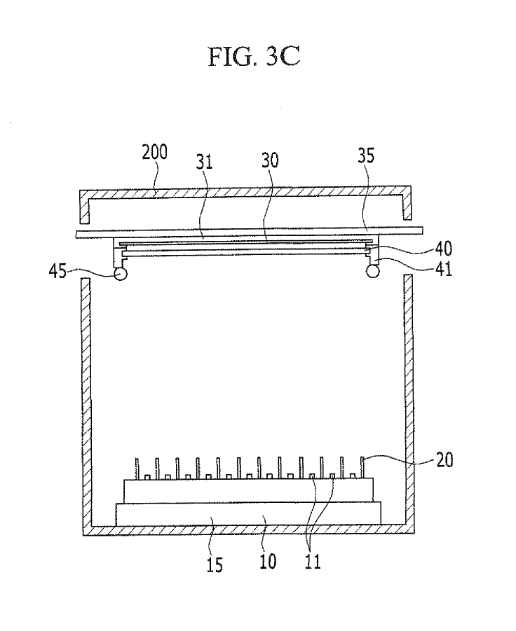

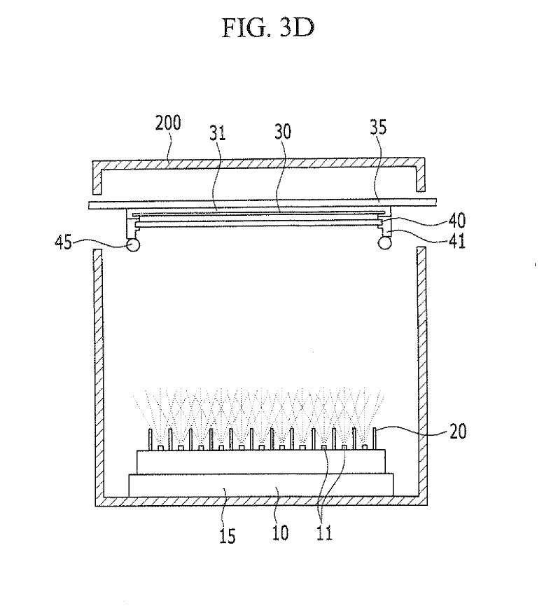

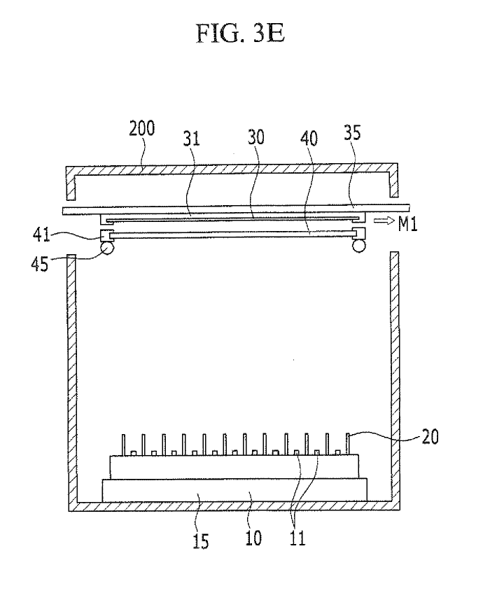

FIG. 3A thru FIG. 3E sequentially show a process for depositing a depositing material on a substrate in a process chamber of a substrate depositing system according to a first exemplary embodiment of the invention. The substrate depositing method will now be described in detail with reference to FIG. 3A thru FIG. 3E.

Referring to FIG. 3A, a deposition source 10 for depositing the depositing material onto the substrate is disposed in the process chamber 200. One end of the nozzle 11 connected to the crucible is arranged so as to face upward so that the depositing material vaporized or sublimated in the crucible in the deposition source may be sprayed toward the substrate.

A cover plate 20 for controlling the deposition angle of the depositing material is disposed near the nozzle 11 of the deposition source 10, and a deposition source guide member 15 for supporting and transferring the deposition source 10 is disposed at the bottom of the deposition source 10.

In order to form an organic thin film or a metal thin film on the substrate, the mask 40 stored in the mask keeping chamber 300 is transferred to the process chamber 200 and is received in the mask fixing device 41. In detail, the mask transferring device 45 can be formed so as to pass through the mask keeping chamber 300 and the process chamber 200, and both ends of the mask 40 are fixed to and received in the mask fixing device 41, and are transferred to the process chamber 200 along the mask transferring device 45.

Furthermore, a gate valve 117 (FIG. 1) may be formed between the mask keeping chamber 300 and the process chamber 200. The gate valve 117 is opened when the mask fixing device 41 (FIG. 3A) is transferred along the mask transferring device 45, and it can be closed after the mask fixing device 41 is transferred.

Referring to FIG. 3B, the mask 40 is transferred to the process chamber 200, and the substrate 30 is transferred into the process chamber 200. In detail, the substrate 30 is fixed to and received in the substrate fixing device 31, the substrate 30 is transferred along the substrate transferring device 35 formed through the process chamber 200, and the substrate 30 is stopped when it reaches the top of the mask 40.

A substrate loading chamber, a substrate unloading chamber, or another process chamber is disposed onto both sides of the process chamber 200, and a gate valve (not shown) can be formed at their connection point. The gate valve is opened when the substrate fixing device 31, having received the substrate 30, is transferred along the substrate transferring device 35, and it can be closed after the substrate fixing device 31 is transferred.

Referring to FIG. 3C, the substrate 30 and the mask 40 are aligned after the substrate 30 and the mask 40 are moved into the process chamber 200.

In this instance, when the gap between the substrate 30 and the mask 40 is formed so as to be wide, a pattern of the thin film deposited on the substrate 30 may not correspond to the opening of the mask 40. That is, when the depositing material which has a predetermined angle and has passed through the opening of the mask 40 reaches the substrate 30, the pattern of the deposited thin film may become greater than the pattern of the opening of the mask 40. Accordingly, in order to minimize the gap between the substrate 30 and the mask 40, the mask fixing device 41 can be closely attached to the substrate fixing device 31 when the substrate 30 and the mask 40 are aligned. Hence, an error in the pattern, such as the organic thin film or the metal thin film, can be minimized by reducing the gap between the substrate 30 and the mask 40.

In consideration of the thickness of the substrate fixing device 31 and the mask fixing device 41, the distance between the substrate transferring device 35 and the mask transferring device 45 can be controlled so as to minimize the gap between the substrate 30 and the mask 40 when they are transferred into the process chamber 200. That is, various methods are applicable in order to form a desired pattern of the thin film deposited on the substrate 30.

The present exemplary embodiment of the invention shows a case of transferring the substrate 30 after transferring the mask 40 into the process chamber 200 for the purpose of reducing the deposition process time. That is, the time consumed in preparing the deposition process can be minimized by performing the depositing process by aligning the substrate 30 and the mask 40 just after transferring the substrate 30 into the process chamber 200. However, the present invention is not restricted thereto, and the mask 40 can be transferred after the substrate 30 is transferred according to the process.

Referring to FIG. 3D, after the substrate 30 and the mask 40 are aligned, the depositing material vaporized or sublimated in the deposition source 10 is sprayed toward the substrate 30 through the nozzle 11. In the present exemplary embodiment, the deposition source 10 is transferred and deposited while the substrate 30 and the mask 40 are stopped. In detail, the depositing material is uniformly deposited on the substrate 30 by transferring the deposition source 10 in the vertical direction with reference to FIG. 3D through the deposition source guide member 15 during the deposition process.

As described above, the cover plate 20 disposed near the nozzle 11 controls the depositing material so as to be uniformly deposited at the center and the edge of the substrate 30 by controlling the deposition angle of the depositing material sprayed by the nozzle 11.

Referring to FIG. 3E, after the deposition process of transferring the deposition source 10 is completed, the substrate fixing device 31 which has received the substrate 30 is transferred to a neighboring chamber. In this instance, when formation of an additional thin film is needed, a process chamber for performing another depositing process is provided nearby. When no additional deposition process is needed after the whole deposition process is completed, the substrate unloading chamber is provided nearby. When the substrate fixing device 31 is transferred, the mask fixing device 41 having received the mask 40, is transferred to the mask keeping chamber 300 (FIG. 1).

The substrate 30 and the mask 40 can be simultaneously transferred. Furthermore, in order to reduce the time consumed by the entire depositing process, and in order to prevent a collision which may be generated when both devices are transferred, it is possible to transfer the substrate 30 in advance of the mask 40. In addition, it is possible of transfer the mask 40 in advance of the substrate 30 according to the process.

When a gate valve is formed between the process chamber 200 and a neighboring chamber, the gate valve which was closed during the deposition process is opened, and the substrate 30 and the mask 40 are transferred.

When a plurality of process chambers 200 are formed, the above-noted deposition process is repeated in each process chamber 200, thereby forming a plurality of organic thin films and metal thin films on the substrate.

Accordingly, the entire depositing process time can be reduced by disposing the mask keeping chamber to one side of the process chamber, separately transferring the substrate and the mask to process chamber, and aligning them. Also, no additional chamber for aligning the substrate and the mask is needed so that a high-resolution organic light emitting element can be formed without employing a large depositing system.

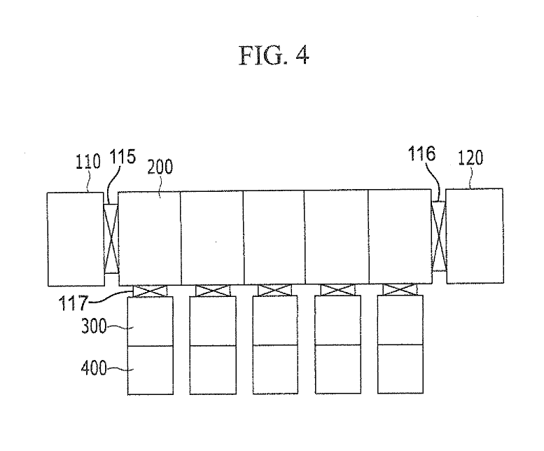

FIG. 4 is a schematic diagram of a substrate depositing system according to a second exemplary embodiment of the invention. The substrate depositing system will now be described in detail. While the second exemplary embodiment is described, the same configurations as in the first exemplary embodiment will be briefly described or not described.

Referring to FIG. 4, the substrate depositing system includes a substrate loading chamber 110, a substrate unloading chamber 120, at least one process chamber 200 disposed between the substrate loading chamber 110 and the substrate unloading chamber 120, and a mask keeping chamber 300 disposed to one side of each process chamber 200. Also, the substrate depositing system includes a mask cleansing chamber 400 disposed to one side of the mask keeping chamber 300.

While depositing materials such as an organic material or a metal, another material may be adhered to the mask during the deposition process. The opening of the mask may be problematically covered because of such depositing materials or other materials, and when this problem occurs, the mask must be cleansed or replaced.

In the present exemplary embodiment of the invention, the mask cleansing chamber 400 is disposed to one side of the mask keeping chamber 300 so that, when the mask has a problem, the corresponding process chamber 200 finishes the deposition process and transfers the mask to the mask cleansing chamber 400, and cleanses it. In this instance, the mask cleansing chamber 400 is formed so as to be a plasma cleansing chamber, and it uses plasma to cleanse the mask.

Accordingly, when the mask has a problem during the deposition process, the problem can be solved without interrupting the entire process, and the process can be quickly restarted when the deposition process is forcibly stopped.

While this disclosure has been described in connection with what is presently considered to be practical exemplary embodiments, it is to be understood that the invention is not limited to the disclosed embodiments but, on the contrary, is intended to cover various modifications and equivalent arrangements included within the spirit and scope of the appended claims.

What is claimed is:

1. A substrate depositing system, comprising:
a substrate loading chamber for receiving a substrate;
a substrate unloading chamber for withdrawing the substrate;
at least one process chamber disposed between the substrate loading chamber and the substrate unloading chamber; and
a mask keeping chamber connected to one side of said at least one process chamber.

2. The substrate depositing system of claim 1, further comprising a substrate transferring device for penetrating said at least one process chamber and transferring a substrate into said at least one process chamber.

3. The substrate depositing system of claim 2, further comprising a substrate fixing device for receiving the substrate, said substrate fixing device being transferred along the substrate transferring device.

4. The substrate depositing system of claim 1, further comprising a mask transferring device for penetrating at least one mutually connected process chamber and the mask keeping chamber.

5. The substrate depositing system of claim 4, further comprising a mask fixing device for receiving a mask, said mask fixing device being transferable along the mask transferring device.

6. The substrate depositing system of claim 1, further comprising a deposition source for depositing a depositing material onto the substrate in said at least one process chamber.

7. The substrate depositing system of claim 6, further comprising a deposition source guide member disposed at a bottom of the deposition source for transferring the deposition source in a given direction.

8. The substrate depositing system of claim 1, further comprising a mask cleansing chamber connected to the mask keeping chamber.

9. The substrate depositing system of claim 8, wherein the mask cleansing chamber is a plasma cleansing chamber.

10. A substrate depositing method, comprising the steps of:
inputting a substrate into a process chamber;
transferring a mask to the process chamber from a mask keeping chamber connected to the process chamber;
aligning the substrate and the mask;
depositing a depositing material onto the substrate while moving a deposition source in the process chamber; and
withdrawing the substrate from the process chamber;
wherein said at least one process chamber is arranged in series with a substrate loading chamber and a substrate unloading chamber, and respective stages are repeated in each said at least one process chamber.

11. The substrate depositing method of claim 10, wherein the substrate is inputted and withdrawn by using a substrate transferring device which penetrates the process chamber, and the mask is transferred by using a mask transfer device for connecting the process chamber and the mask keeping chamber.

12. The substrate depositing method of claim 11, wherein the substrate and the mask are received in a substrate fixing device and a mask fixing device, respectively, and the substrate fixing device and the mask fixing device are movable on the substrate transferring device and the mask transferring device, respectively.

13. The substrate depositing method of claim 10, wherein the deposition source moves in a direction crossing a direction in which the substrate is inputted and withdrawn.

14. The substrate depositing method of claim 10, further comprising the steps, after the depositing of a substrate, of transferring the mask to a mask cleansing chamber connected to the mask keeping chamber, and cleansing the mask.

15. The substrate depositing method of claim 14, wherein the cleansing of the mask includes cleansing the mask by using plasma.
